(19) United States
(12) Patent Application Publication
(10) Pub. No.: US 2026/0280230 A1
(43) Pub. Date: Sep. 17, 2026

(54) ZERO THICKNESS PLANARIZATION OF OVERGROWN SEMICONDUCTOR STRUCTURES

(71) Applicant: NATIONAL RESEARCH COUNCIL OF CANADA, Ottawa, Ontario (CA)

(72) Inventor: Bernard Paquette, Orléans (CA)

(21) Appl. No.: 19/167,529

(22) PCT Filed: Mar. 20, 2024
(86) PCT No.: PCT/IB2024/052681

§ 371 Date: Sep. 22, 2025

Related U.S. Application Data
(60) Provisional application No. 63/491,558, filed on Mar. 22, 2023.

(51) Int. Cl. H01S 5/12

(52) U.S. Cl. CPC H01S 5/1231; H01S 2304/04

(57) ABSTRACT

A bottom grating semiconductor device, such as a DFB laser, and method of fabricating a bottom grating semiconductor device for increasing Kappa value, comprising overgrowing a planarization layer on a grating layer of the semiconductor device, wherein the grating layer includes a plurality of Bragg gratings, etching back the planarization layer to a desired thickness over the grating layer, and growing an active layer on the etched back planarization layer.

### BACKGROUND OF THE INVENTION

### 1. Field of the Invention

The present invention relates to fabrication of distributed-feedback (DFB) lasers, and in particular to a method for increasing the Kappa value for high coupling DFB lasers having a bottom grating structure.

### 2. Description of the Related Art

A DFB laser is a type of laser diode, quantum-cascade laser or optical-fiber laser comprising a grating layer and an active layer. The grating layer comprises a material with a higher refractive index (e.g. GaInAsP) embedded in a lower refractive index material (e.g. InP). A periodic structure is etched into this layer, and the structure is then backfilled (e.g. with InP).

DFB lasers can be either a top grating, or a bottom grating structure, defined by whether the grating layer is above or below the active region. Lasers are typically p-doped above the active region, and n-doped below the active region. Bottom gratings are generally preferable, as the presence of the grating layer in the p-doped material hinders current flow through the active region, while the effect is much reduced on the n-side.

Light is generated in the active layer of a DFB laser, although the light mode extends past the active region and partially overlaps the grating layer. This overlap, the thickness of the grating layer, and the refractive index of the grating layer all affect the Kappa value, which represents the amount of coupling (i.e. interaction) between the gratings and the light outside of the active region. A greater amount of light overlapping the grating results in a higher Kappa value. A high Kappa value is advantageous for some applications, such as high speed directly modulated lasers.

However, there are limitations to increasing the Kappa value, including limitations on the thickness of the grating layer due to the fabrication method for the gratings, and limitations on the refractive index of the grating layer due to the composition of the gratings at which absorption of light by the gratings becomes non-negligible.

In a top grating configuration, the gratings can generally be brought closer to the active region to increase the overlap between the light mode and the gratings before growing subsequent layers in the device, and thereby maximize performance. In a bottom grating configuration, the extent to which the gratings can be brought closer to the active region is limited by the planarization thickness above the gratings; the fact that backfilling of InP in the gratings must reach a planar surface before the active region can be grown, and the thickness needed to reach this planar surface being of the same order of magnitude as the thickness of the gratings themselves.

There therefore exists a problem in increasing Kappa value in bottom grating configurations.

The following is relevant to this disclosure:
K. Takagi et al., “120° C. 10-GB/s uncooled direct Modulated 1.3-μm AlGaInAs MQW DFB laser diodes,” in IEEE Photonics Technology Letters, vol. 16, no. 11, pp. 2415-2417, November 2004, doi: 10.1109/LPT.2004.834926.
D. Takemoto, K. Nakahara, T. Tsuchiya, T. K. Sudoh and S. Tsuji, “Dislocation free strained InGaAlAs-MQW growth over an InGaAsP/InP grating,” Conference Proceedings. 2001 International Conference on Indium Phosphide and Related Materials. 13th IPRM (Cat. No.01CH37198), 2001, pp. 394-397,

[symbol]

### SUMMARY OF THE INVENTION

It is an aspect of the present invention to provide a method for increasing the Kappa value for high coupling bottom grating semiconductor devices, such as DFB lasers.

In an aspect, a metal-organic chemical vapor deposition (MOCVD) method is used to overgrow gratings with zero thickness planarization, in order to minimize the distance between the active region of the laser and the grating layer in a bottom grating configuration of a DFB laser.

In embodiments, a n-type InP substrate having fabricated and grown gratings of GaInAsP is placed in a MOCVD reactor where the gratings are overgrown until planarized, and then etched back in-situ to a desired thickness. The etched back structure is then overgrown with a final device structure. In embodiments, the gratings can be 55 nm.

The above aspects can be attained by a method for increasing Kappa value in a bottom grating semiconductor device, comprising overgrowing a planarization layer on a grating layer of the semiconductor device, wherein the grating layer includes a plurality of Bragg gratings; etching back the planarization layer to a desired thickness over the grating layer; and growing an active layer on the etched back planarization layer

[symbol]

In another aspect, there is provided a bottom grating semiconductor device having high Kappa value, comprising a grating layer having a plurality of Bragg gratings; a planarization layer overgrown on said grating layer and etched back to a desired thickness over the grating layer; and an active layer grown on the etched back planarization layer.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 shows bottom grating overgrown with alternating InP/InGaAs layers as marker layers to demonstrate typical planarization thicknesses.

FIG. 2 shows a bottom grating DFB laser planarized according to an embodiment.

FIG. 3 is a schematic illustration showing steps of a planarization method according to an embodiment, comprising steps of overgrowing an underlying structure in FIG. 3A, etching back the overgrown portion in FIG. 3B and growing additional layers on the etched back portion in FIG. 3B.

FIG. 4 is a flowchart of the planarization method used in FIG. 3, according to an embodiment.

### DETAILED DESCRIPTION OF THE PREFERRED EMBODIMENTS

As discussed above, during fabrication of a bottom grating semiconductor device, such as a DFB laser, material with high refractive index (e.g. GaInAsP) is embedded in a lower refractive index material (e.g. InP) and then etched to create a layer of Bragg gratings. The grating layer is then planarized in preparation for overgrowth to create additional layers. As a specific example, bottom grating DFB lasers have the active layers grown on top of the gratings, and a smooth surface is required before growing the active region.

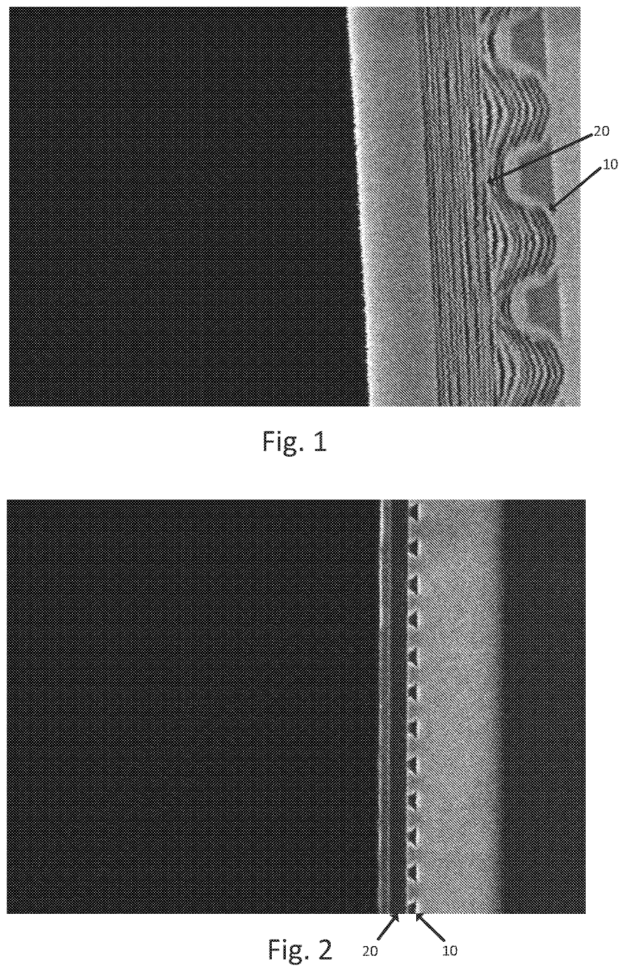

FIG. 1 shows bottom grating (10) overgrown with alternating InP/InGaAs layers (20) as marker layers to demonstrate typical planarization, where the smooth continuous layer forms at approximately 50 nm above the top of the grating layer, defined as the planarization thickness.

As set forth below, a method is provided for reducing the planarization thickness to zero. FIG. 2 shows a bottom grating DFB laser planarized according to the method set forth below, where a smooth, continuous layer 20 is obtained at the top of the gratings 10.

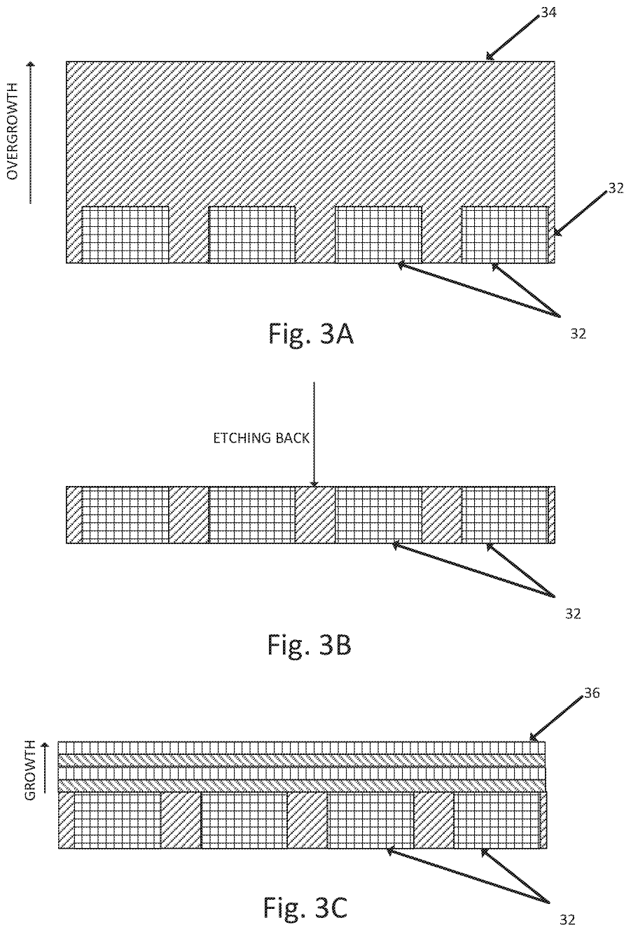

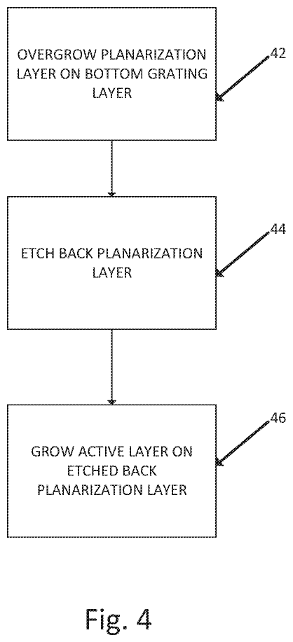

FIG. 3 shows planarization of a bottom grating DFB laser and FIG. 4 is a flowchart of an exemplary planarization method. In FIG. 3A, the grating layer 30 of the DFB laser, including Bragg gratings 32, is overgrown until planarization is obtained according to step 40 in FIG. 4, resulting in a planarization layer 34. In FIG. 3B and according to step 42 in FIG. 4, the overgrown planarization layer 34 is etched back in-situ until a desired thickness is achieved. In FIG. 3C and according to step 44 in FIG. 4, an active layer 36 is grown over the etched back planarization layer 34. An advantage of the method is that it creates additional design space around semiconductor devices. As a specific example, active layer 36 can be grown close to the bottom gratings 32, which allows for higher Kappa values and faster direct modulation lasers.

According to embodiments, in the overgrowth step 40 the grating layer 30 can be overgrown to create a planarization layer 34 of InP >10 nm in thickness using typical growth conditions for MOCVD. For example, PH₃ can be introduced in the MOCVD reactor (chamber) directly as a gas, and TMIn can be introduced by flowing H2 as a carrier gas through a TMIn bubbler. The overgrowth step 40 can be performed during a temperature ramp where the onset of growth occurs at approximately 575° C., is ramped to 625° C., and subsequently maintained at 625° C. for the rest of the growth (through steps 42 and 44). In an exemplary embodiment, a pressure of 100 mbar, and a growth rate of 0.5 nm/s can be used. Typical thicknesses used can be approximately 200 nm for the first InP layer. Other precursors, such as tertiarybutylphosphine, can also be used for step 40, and specific parameters such as the temperature can also be modified. The growth step 40 can be halted while maintaining a flow of PH₃ to preserve the planarization layer surface.

In the etching step 42, an etchant gas species can be introduced in the MOCVD reactor, using CBrCl3 as a precursor as an example (other usable precursors include CBr4, CCl3, C2H5Cl, PCl, C3H7Cl, or CH2Cl2, C2H5I, HCl), while still maintaining the flow of PH₃. This etchant gas flow can be maintained for a period of time sufficient to etch the previously grown InP layer 34, this time being determined by precise calculation and calibration, or by observing thickness oscillations using in-situ reflectometry. This period of time should be sufficient to reach a thickness <10 nm of InP layer 34 above the gratings 32. The etch is then interrupted by stopping the flow of etchant gas, while still maintaining the PH₃ flow.

As shown in FIG. 3B, the planarization layer 34 is preferably completely etched back to zero (i.e. to the gratings 32) or almost zero (e.g. a range of 0-50 nm) depending on the application. In prior art the desired thickness is limited by planarization and therefore cannot be less than approximately 50 nm.

In the growth step 46, according to embodiments the active region 36 can comprise alternating layers of GaInAsP or AlGaInAs of different compositions. Precursors used can be a combination of TMIn, TMGa, TEGA, TMAl, PH₃, AsH₃ at appropriate flows to achieve the desired compositions. In embodiments, active region 36 can be grown to a total thickness of 25 nm-200 nm.

In summary, a fabrication method is set forth that combines growth, in-situ etch, and additional growth to achieve planarization of very low thickness, including zero thickness. The exemplary method can be used to fabricate bottom grating DFBs, such as direct modulation lasers (DMLs), having increased grating coupling strength (Kappa value), and thereby unlock optimal bottom grating design space.

It is also contemplated that the exemplary method can be applied to other devices that integrate lasers and amplifiers in a single device, such as a semiconductor optical amplifiers (SOAs).

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A method for increasing Kappa value in a bottom grating semiconductor device, comprising:
overgrowing a planarization layer on a grating layer of the semiconductor device, wherein the grating layer includes a plurality of Bragg gratings;
etching back the planarization layer to a desired thickness over the grating layer; and
growing an active layer on the etched back planarization layer.

2. The method of claim 1, wherein overgrowing the planarization layer, etching back the planarization layer and growing the active layer are performed in-situ using metal-organic chemical vapor deposition (MOCVD).

3. The method of claim 2, wherein overgrowing the planarization layer comprises:
ramping up temperature and pressure inside a reactor to growth conditions;
introducing precursors in the reactor to start growth of the planarization layer; and
maintaining temperature, pressure and precursors in the reactor until a desired planarization layer thickness is reached.

4. The method of claim 3, wherein the overgrowth precursors comprise PH3 and TMIn.

5. The method of claim 3, wherein the precursors include tertiarybutylphosphine.

6. The method of claim 3, further including maintaining a flow of PH3 to preserve a surface of the planarization layer prior to etching back the planarization layer.

7. The method of claim 6, wherein the etching back comprises introducing an etchant gas using an etchant precursor while maintaining the flow of PH3 for a period of time sufficient to etch the planarization layer to the desired thickness.

8. The method of claim 7, wherein the period of time is sufficient to etch the planarization layer back to a thickness of <50 nm above the Bragg gratings, after which the flow of etchant gas is stopped while maintaining the flow of PH3.

9. The method of claim 8, wherein the etchant precursor is one of either CBrCl3, CBr4, CCl3, C2H5Cl, PCl, C3H7Cl, or CH2Cl2, C2H5I, or HCl.

10. The method of claim 7, wherein growing the active layer comprises introducing a combination of active layer growth precursors.

11. The method of claim 9, wherein the active layer growth precursors comprise a flow of two or more of TMIn, TMGa, TEGA, TMAl, PH3, AsH3.

12. A bottom grating semiconductor device having high Kappa value, comprising:
a grating layer having a plurality of Bragg gratings;
a planarization layer overgrown on said grating layer and etched back to a desired thickness over the grating layer; and
an active layer grown on the etched back planarization layer.

13. The bottom grating semiconductor device of claim 12, wherein the grating layer comprises a material with a high refractive index embedded in a lower refractive index material.

14. The bottom grating semiconductor device of claim 13, wherein the semiconductor device is a bottom grating distributed-feedback (DFB) laser.

15. The bottom grating semiconductor device of claim 13, wherein the high refractive index material is InP and the lower refractive index material is GaInAsP.

16. The bottom grating semiconductor device of claim 15, wherein the planarization layer comprises n-type InP.

17. The bottom grating semiconductor device of claim 16, wherein the grating layer is approximately 55 nm thick and the planarization layer is etched back from a first thickness greater than 10 nm to the desired thickness.

18. The bottom grating semiconductor device of claim 17, wherein the first thickness is approximately 200 nm and the desired thickness is from 0-50 nm.

19. The bottom grating semiconductor device of claim 17, wherein the active region comprises alternating layers of GaInAsP or AlGaInAs.

20. The bottom grating semiconductor device of claim 19, wherein the thickness of the alternating layers of GaInAsP or AlGaInAs is approximately 25 to 200 nm.
